(19) United States
(12) Patent Application Publication
(10) Pub. No.: US 2011/0148854 A1
(43) Pub. Date: Jun. 23, 2011

(54) VOLTAGE SUPPLY CIRCUIT AND DISPLAY APPARATUS

(75) Inventor: Hirokata UEHARA, Kawasaki (JP)

(73) Assignee: FUJITSU LIMITED, Kawasaki-shi (JP)

(21) Appl. No.: 12/966,233

(22) Filed: Dec. 13, 2010

(30) Foreign Application Priority Data
Dec. 18, 2009 (JP) 2009-287960

(51) Int. Cl. G09G 3/36; H03K 17/00; G09G 5/00

(52) U.S. Cl. 345/213; 327/365; 345/87

(57) ABSTRACT

A voltage supply circuit includes a switching circuit to switch among a plurality of driving voltages including a first driving voltage and a second driving voltage lower than the first driving voltage based on an operation mode of a display apparatus and control at least one of a switching speed and a switching timing so that one of a first switching speed and a first switching timing to the first driving voltage becomes faster than a corresponding one of a second switching speed and a second switching timing to the second driving voltage.

### CROSS-REFERENCE TO RELATED APPLICATIONS

This application claims the benefit of priority from Japanese Patent Application No. 2009-287960 filed on Dec. 18, 2009, the entire contents of which are incorporated herein by reference.

### BACKGROUND

1. Field

Embodiments discussed herein relate to a voltage supply circuit and a display apparatus.

2. Description of Related Art

Display methods for electronic paper include a display method that uses a liquid crystal composition including a cholesteric phase. The liquid crystal composition including the cholesteric phase includes cholesteric liquid crystals. The cholesteric liquid crystals may be referred to as chiral nematic liquid crystals. In the cholesteric liquid crystals, a chiral additive is added to a nematic liquid crystal to form a helical cholesteric phase including nematic liquid crystal molecules. The cholesteric liquid crystals includes a semi-permanent display holding characteristic, a vivid color display characteristic, a high contrast ratio, and a high resolution characteristic.

A display apparatus may perform multi-color display using a cholesteric liquid crystal layer that selectively reflects light with different wavelengths. The display apparatus controls voltages applied to display elements to set a planar state where light with a certain wavelength is reflected, a focal conic state where light is transmitted, and an intermediate state between the planar state and the focal conic state.

Related art is disclosed in Japanese Laid-open Patent Publication No. 2009-251453.

### SUMMARY

According to one aspect of the embodiments, a voltage supply circuit includes a switching circuit to switch among a plurality of driving voltages including a first driving voltage and a second driving voltage lower than the first driving voltage based on an operation mode of a display apparatus and control at least one of a switching speed and a switching timing so that one of a first switching speed and a first switching timing to the first driving voltage becomes faster than one a corresponding one of a second switching speed and a second switching timing to the second driving voltage.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 illustrates an exemplary display apparatus;

FIGS. 2A, 2B and 2C illustrate an exemplary driving of a display element circuit;

FIG. 3A illustrates an exemplary segment drive;

FIG. 3B illustrates an exemplary common driver;

FIGS. 4A and 4B illustrate an exemplary output voltage;

FIGS. 5A and 5B illustrate an exemplary examples output voltage;

FIG. 6 illustrates an exemplary polarity of an output voltage;

FIGS. 7A, 7B and 7C illustrate an exemplary multi-voltage generating circuit;

FIG. 8 illustrates an exemplary driver;

FIG. 9 illustrates an exemplary erase voltage;

FIGS. 10A and 10B illustrate an exemplary output voltage of a driver;

FIGS. 11A and 11B illustrate an exemplary voltage switching;

FIG. 12 illustrates an exemplary voltage;

FIG. 13 illustrates an exemplary voltage;

FIG. 14 illustrates an exemplary voltage supply circuit;

FIG. 15 illustrates an exemplary output voltage;

FIG. 16 illustrates an exemplary voltage supply circuit;

FIG. 17 illustrates an exemplary voltage supply circuit;

FIG. 18 illustrates an exemplary current limiter circuit;

FIG. 19 illustrates an exemplary voltage supply circuit;

FIG. 20 illustrates an exemplary output voltage;

FIG. 21 illustrates an exemplary voltage supply circuit; and

FIG. 22 illustrates an exemplary voltage supply circuit.

### DESCRIPTION OF EMBODIMENTS

In a display apparatus including a cholesteric liquid crystal, a display element portion including display elements arranged in a matrix form, for example, a display panel, is driven by a segment driver and a common driver. The segment driver outputs a voltage corresponding to one line of image data to the display element portion. The common driver outputs a voltage corresponding to a selected line position to the display element portion. Since the display apparatus holds a display image, the display image is erased before rewritten. The output voltages of the segment driver and the common driver during drawing of a display image may be different from the output voltages of the segment driver and the common driver during erasing of the display image. Therefore, the voltage supply circuit supplies at least two different voltages to the segment driver and the common driver.

When switching voltages between the erasing of an image and the drawing of an image is not normally performed in the voltage supply circuit, the output voltage of the segment driver and the output voltage of the common driver do not satisfy a certain relationship, which may cause the image to display abnormally.

For example, a plurality of driving voltages may be supplied to the driving circuit of the display apparatus. The driving voltages are switched depending on the operation mode of the display apparatus. A switching speed or a switching timing of a first driving voltage may be faster than a corresponding switching speed or a switching timing of a second driving voltage which is lower than the first driving voltage.

A simple voltage supply circuit switches between the driving voltages depending on an operation mode corresponding to the erasing or drawing of an image on the display apparatus. Since at least two different voltages are supplied from the voltage supply circuit, the output voltage of the segment driver and the output voltage of the common driver satisfy the certain relationship.

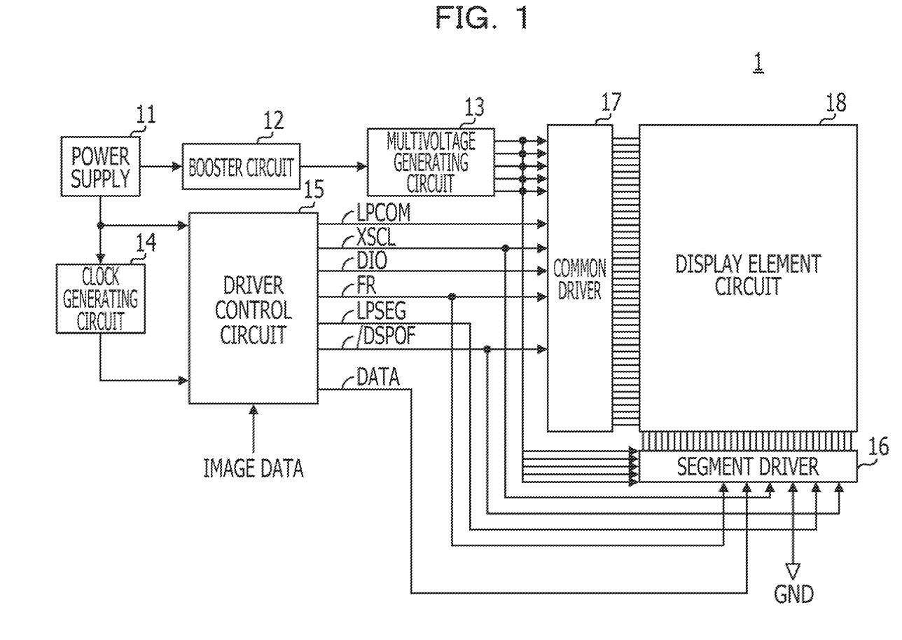

FIG. 1 illustrates an exemplary display apparatus. The display apparatus 1 illustrated in FIG. 1 may include a memory function and may be a color display apparatus including a cholesteric liquid crystal.

The display apparatus 1 includes a power supply 11, a booster circuit 12, a multi-voltage generating circuit 13, a clock generating circuit 14, a driver control circuit 15, a segment driver 16, a common driver 17, and a display element circuit (or a display panel) 18.

The multi-voltage generating circuit 13 may include a voltage supply circuit. The voltage supply circuit may include a first amplifier circuit and a second amplifier circuit. The voltage supply circuit may include the first amplifier circuit, the second amplifier circuit, and a current limiter circuit. The voltage supply circuit may include the first amplifier circuit, the second amplifier circuit, and a booster circuit. The voltage supply circuit may include a first switch and a second switch.

The power supply 11 outputs a power supply voltage of, for example, 3 volts (V) to 5 V. The booster circuit 12 includes a regulator, such as a DC-DC converter, and increases the power supply voltage from the power supply 11 to, for example, 24V to 40V. The booster circuit 12 including the regulator may employ an integrated circuit (IC). The integrated circuit IC adjusts a boost voltage based on a feedback voltage. Since a plurality of voltages generated by resistive potential division or the like are selected and supplied to a feedback terminal, the boost voltage changes. The multi-voltage generating circuit 13 performs resistive division or the like on the boost voltage from the booster circuit 12 to generate various voltages and stabilizes the generated voltages. The voltages generated by the multi-voltage generating circuit 13 are supplied as driving voltages to the segment driver 16 and the common driver 17.

The clock generating circuit 14 generates a clock corresponding to the operation timing of the display apparatus 1. The driver control circuit 15 generates various control signals based on the clock and image data and supplies the control signals to the segment driver 16 and the common driver 17. The driver control circuit 15 may be, for example, a microcomputer, a central processing unit (CPU), a field programmable gate array (FPGA), or a complex programmable logic device (CPLD).

The segment driver 16 outputs a voltage corresponding to one line of image data to the display element circuit 18. The common driver 17 outputs a voltage corresponding to a selected line position to the display element circuit 18. For example, the segment driver 16 may drive 768 data lines, and the common driver 17 may drive 1,024 scan lines. Since image data given to individual red/green/blue (RGB) pixels differs, the segment driver 16 may independently drive the individual data lines. The common driver 17 may drive RGB lines in common. Image data to be supplied to the segment driver 16 may be 4-bit data in which, for example, a full-color original image is converted to 4,096-color data—of RGB each having 16 gray levels by an error diffusion method. A method for use in the gray level conversion may have a high display quality and may be a blue noise mask method according to the error diffusion method.

The display element circuit 18 may include a configuration where 1,024×768 display pixels are arranged in a matrix form according to an A4-size XGA (extended graphics array) specification. The display element circuit 18 may either have or not have flexibility in application.

The power supply 11, the booster circuit 12, the clock generating circuit 14, the driver control circuit 15, the segment driver 16, the common driver 17, and the display element circuit 8 each may be any such known device. In the display apparatus 1, the multi-voltage generating circuit 13 may switch between a voltage for erasing an image and a voltage for drawing an image.

The driver control circuit 15 outputs image data Data to the segment driver 16. The driver control circuit 15 outputs, as control signals, a data-latch scan shift signal LPCOM indicating a scan line that the common driver 17 scans, a data capture clock XSCL for controlling image-data transfer timing, a frame start signal DIO indicating starting of a display line, a pulse-polarity control signal FR indicating inversion of the polarities of voltages supplied to the segment driver 16 and the common driver 17, a data-latch scan shift signal LPSEG indicating an update of a display line, a driver-output off signal DSPOF that turns off voltages supplied to the segment driver 16 and the common driver 17, etc. The segment driver 16 and the common driver 17 display an image corresponding to image data on the display element circuit 18.

The data capture clock XSCL may not be supplied to the common driver 17. The frame start signal DIO is supplied to the common driver 17. A signal supplied to the segment driver 16, which corresponds to the frame start signal DIO, may be a ground signal GND.

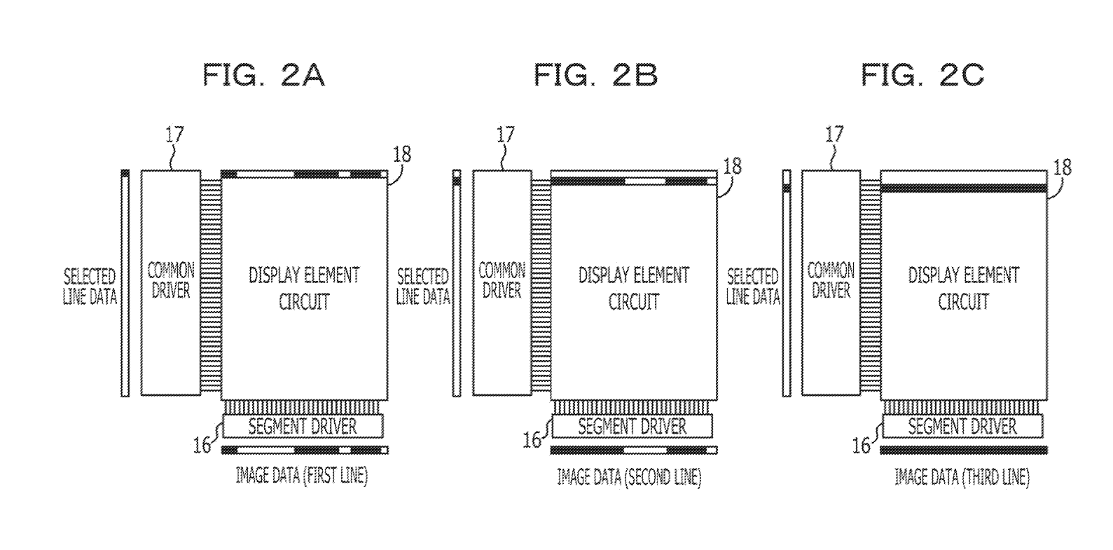

FIGS. 2A to 2C illustrate an exemplary driving of a display element circuit. The display element circuit illustrated in FIGS. 2A to 2C may be the display element circuit 18 illustrated in FIG. 1. The segment driver 16 outputs a voltage corresponding to one line of image data. The common driver 17 outputs an on/off voltage corresponding to a selected line position. In FIGS. 2A to 2C, the positions of selected display pixel and display element are indicated in black. FIG. 2A illustrates a case where the display pixels of image data on the first line are selected. FIG. 2B illustrates a case where the display pixels of image data on the second line are selected. FIG. 2C illustrates a case where the display pixels of image data on the third line are selected.

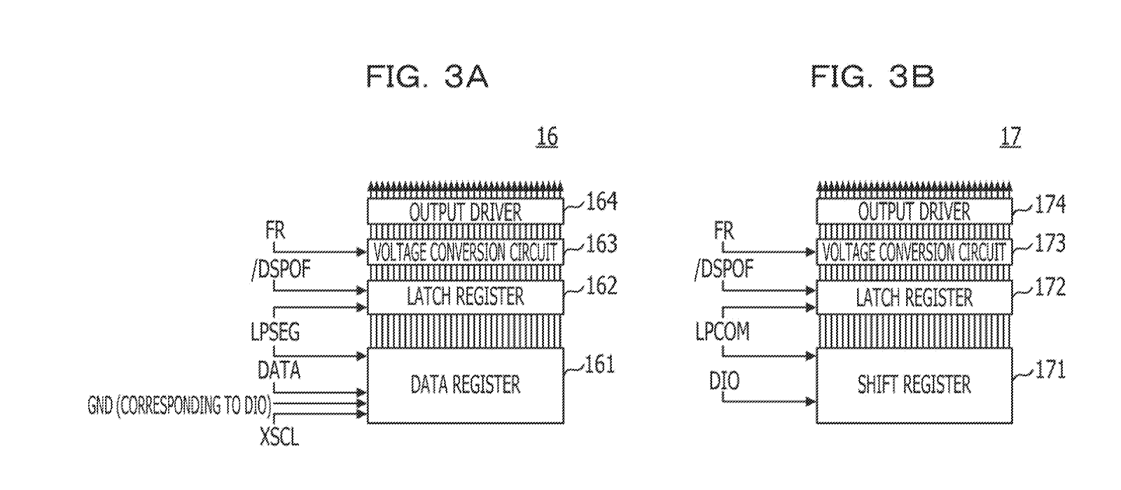

FIG. 3A illustrates an exemplary segment driver. FIG. 3B illustrates an exemplary common driver. The segment driver 16 and the common driver 17 illustrated in FIGS. 3A and 3B may perform matrix display.

As illustrated in FIG. 3A, the segment driver 16 includes a data register 161, a latch register 162, a voltage conversion circuit 163, and an output driver 164. In the segment driver 16, image data from the data register 161 is latched by the latch register 162 based on the data-latch scan shift signal LPSEG. A voltage corresponding to the image data stored in the latch register 162 is converted to a voltage suitable for driving the display element circuit 18 by the voltage conversion circuit 163 and is thereafter output via the output driver 164. Since buffers for two lines including the data register 161 and the latch register 162 are provided, image data on the line next to the image data Data is stored in the data register 161 based on the frame start signal DIO and the data capture clock XSCL while a voltage corresponding to the image data in the latch register 162 is being output. The segment driver 16 outputs a voltage corresponding to one line of image data to the display element circuit 18.

As illustrated in FIG. 3B, the common driver 17 includes a shift register 171, a latch register 172, a voltage conversion circuit 173, and an output driver 174. The frame start signal DIO is shifted based on the data-latch scan shift signal LPCOM into the latch register 172. A voltage corresponding to a selected line position stored in the latch register 172 is converted to a voltage suitable for driving the display element circuit 18 by the voltage conversion circuit 173 and is output via the output driver 174. The common driver 17 outputs a voltage corresponding to the selected line position to the display element circuit 18.

The segment driver 16 and the common driver 17 scan the display element circuit 18 from one line to another line.

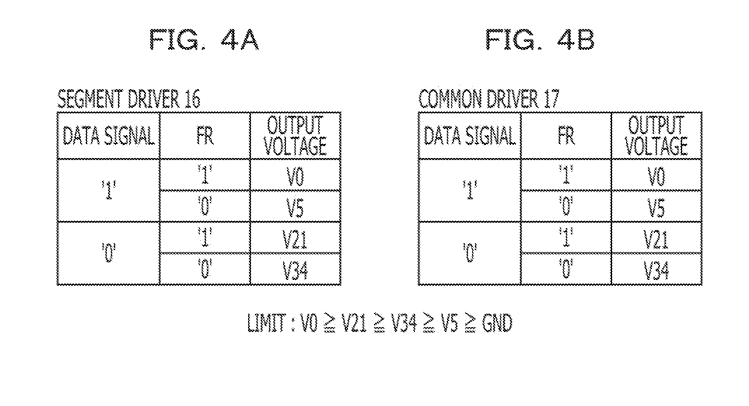

FIGS. 4A and 4B illustrate an exemplary output voltage. The output voltages illustrated in FIGS. 4A and 4B may be output voltages of the segment driver 16 and the common driver 17. FIG. 4A illustrates output voltages corresponding to a data signal and a pulse-polarity control signal FR supplied to the segment driver 16. FIG. 4B illustrates output signals corresponding to a data signal and a pulse-polarity control signal FR supplied to the common driver 17. The output voltages of the segment driver 16 and the common driver 17 may be V0, V5, V21, or V34. The output voltage of the segment driver 16 may be expressed as V21S or V34S that is given by adding S to V21 or V34. The output voltage of the common driver 17 may be expressed as V21C or V34C that is given by adding C to V21 or V34.

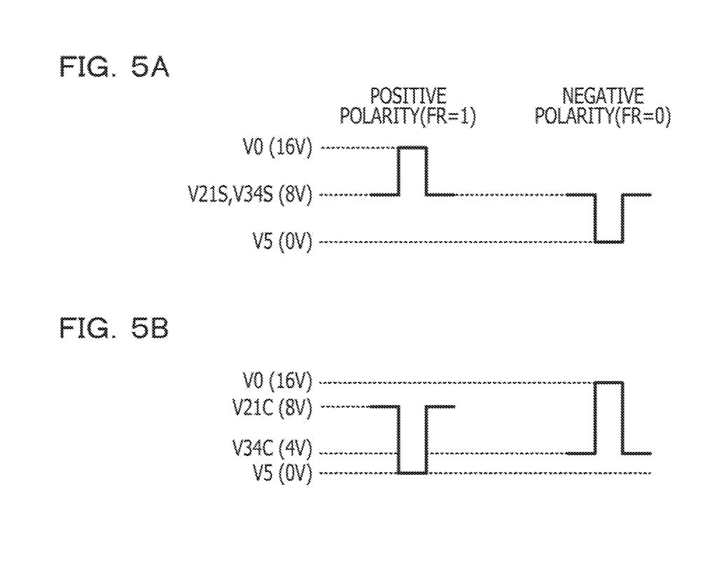

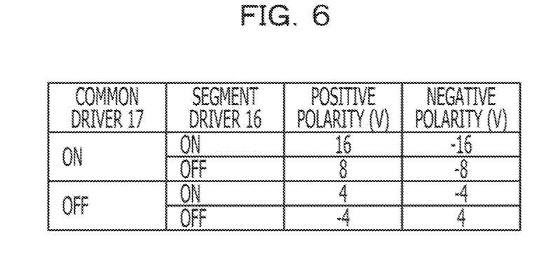

FIGS. 5A and 5B illustrate an exemplary output voltage. The output voltage illustrated in FIGS. 5A and 5B may be output voltages of the segment driver 16 and the common driver 17. FIG. 6 illustrates an exemplary polarity of output voltages. The polarities of the output voltages illustrated in FIG. 6 may be the polarities of the segment driver 16 and the common driver 17. FIG. 5A illustrates the output voltages V0, V21S, V34S, and V5 of the segment driver 16. FIG. 5B illustrate the output voltages V0, V21C, V34C, and V5 of the common driver 17. The output voltages V0, V21S, V21C, V34C, V34S, and V5 may satisfy V0=16 V, V21S=V34S=8 V, V5=0 V, V21C=8 V, and V34C=4 V.

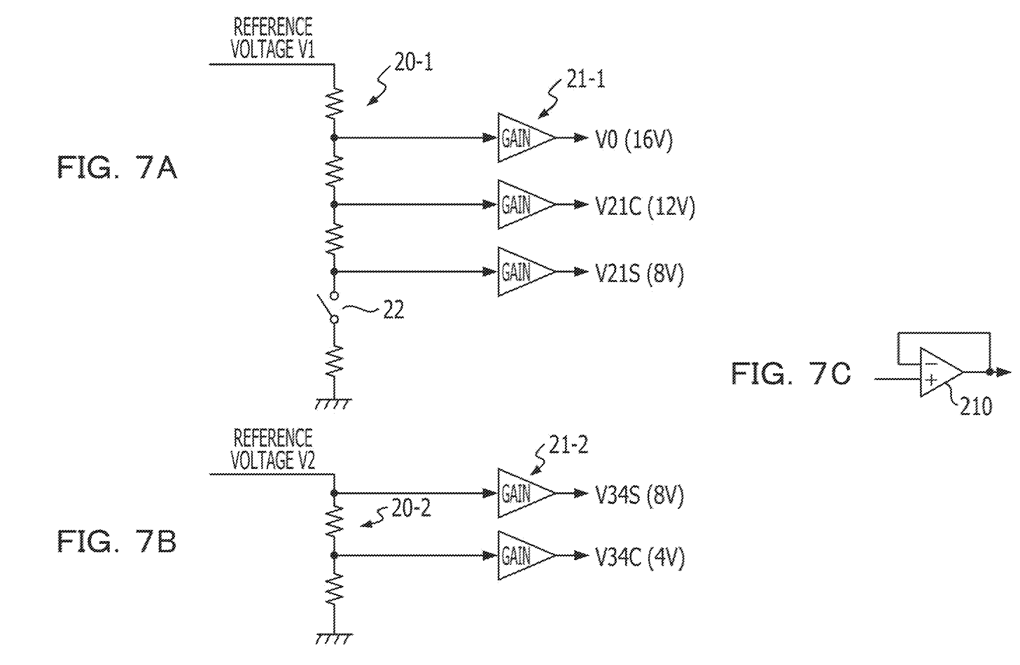

FIGS. 7A, 7B, and FIG. 7C illustrate an exemplary multi-voltage generating circuit. FIG. 7A illustrates a voltage supply circuit that generates various voltages based on a reference voltage V1 from the booster circuit 12. FIG. 7B illustrates a voltage supply circuit that generates various voltages based on a reference voltage V2 from the booster circuit 12. FIG. 7C illustrates a driver. In FIG. 7A, a resistor group 20-1 includes a plurality of resistors that are coupled in series between the reference voltage (power supply) V1 and the ground (0 V). An amplifier circuit group 21-1 includes a plurality of amplifier circuits coupled to nodes that couple adjacent resistors in the resistor group 20-1. The voltage supply circuit illustrated in FIG. 7A supplies the output voltage V0, V21C, or V21S. A switch 22 is disposed in the resistor group 20-1. In FIG. 7B, the resistor group 20-2 includes a plurality of resistors that are coupled in series between the reference voltage (power supply) V2 and the ground. The amplifier circuit group 21-2 includes a plurality of amplifier circuits that are coupled to nodes in the resistor group 20-2. The voltage supply circuit illustrated in FIG. 7B supplies the output voltage V34S or V34C. The amplifier circuits (Gain) in the amplifier circuit group 21-1 and the amplifier circuit group 21-2 (Gain) may each include, for example, an operational amplifier 210 illustrated in FIG. 7C.

When the display element circuit 18 draws an image, the switch 22 is turned on, and the segment driver 16 outputs the output voltage V0=16 V, V21S=8 V, or V34S=8 V. The common driver 17 outputs the output voltage of V0=16 V, V21C=12 V, or V34C=4 V. The output voltages of the segment driver 16 may have the relation of V0≧V21S≧V34S≧V5≧0 V. The output voltages of the common driver 17 may have the relation of V0≧V21C≧V34C≧V5≧0 V. The output voltages of the segment driver 16 and the common driver 17 during drawing may have the relation of V0≧V21≧V34≧V5≧0 V.

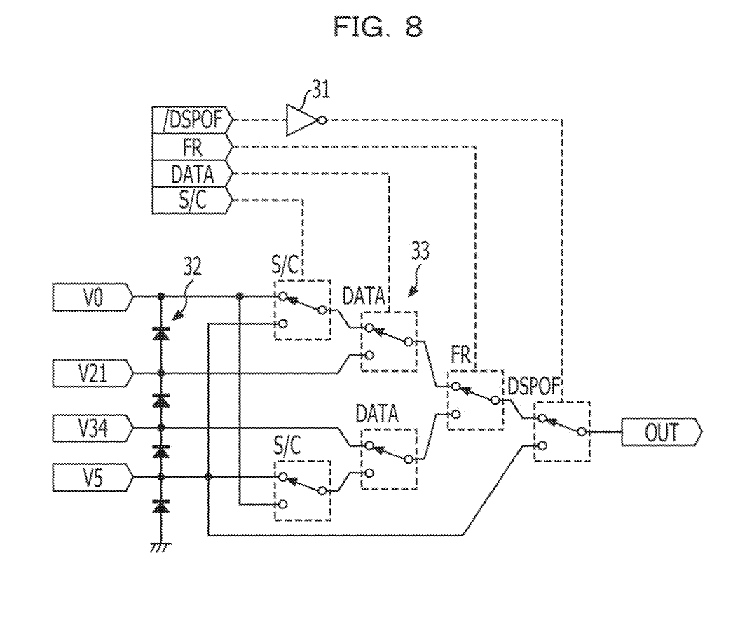

FIG. 8 illustrates an exemplary driver. The driver illustrated in FIG. 8 may be the segment driver 16 or the common driver 17. The driver includes an inverter 31, a diode group 32 including four protection diodes or parasitic diodes, and a switch group 33 including six switches. The switch group 33 includes two switches that are controlled by a segment/common switching signal S/C, two switches that are controlled by the image data Data, one switch that is controlled by the pulse-polarity control signal FR, and one switch that is controlled by the driver-output off signal DSPOF. The driver outputs one of the voltages V0, V21, V34, and V5 from the multi-voltage generating circuit 13 as an output voltage OUT based on the switching control of the switch group 33. When the segment/common switching signal S/C is set to a first level, the driver shown in FIG. 8 may be used as the segment driver 16. When the segment/common switching signal S/C is set to a second level, the driver illustrated in FIG. 8 may be used as the common driver 17.

When the output voltage of the driver illustrated in FIG. 8 does not have the relation of V0≧V21≧V34≧V5≧0 V, a through current may flow via a diode disposed between nodes having the potential of V0, V21, V34, or V5. Since the through current flows in the driver, there is no need for the output voltage of the segment driver 16 and the output voltage of the common driver 17 to have the foregoing relation.

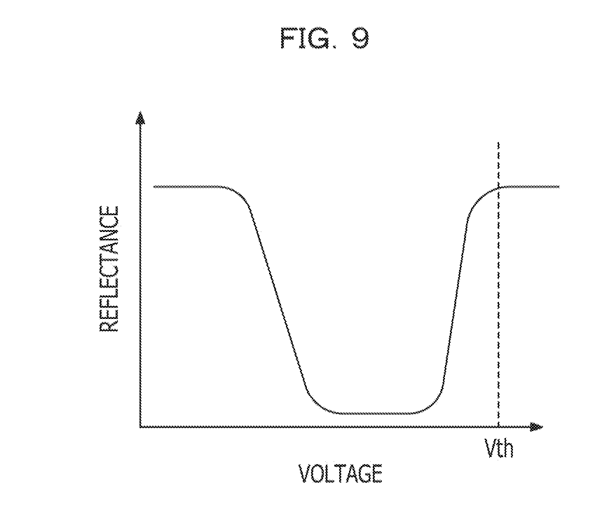

FIG. 9 illustrates an exemplary erase voltage. The display apparatus 1 including a cholesteric liquid crystal may have a memory function of storing display content. An image is erased before rewriting of the display. The vertical axis illustrated in FIG. 9 indicates the reflectance of the cholesteric liquid crystal layer of the display element circuit 18 in any unit. The horizontal axis illustrated in FIG. 9 indicates an erase voltage in any unit. For example, an erase voltage that is equal to or higher than a threshold voltage Vth is supplied to the display element circuit 18, so that the display image is erased. The threshold voltage Vth may be 28 V, for example.

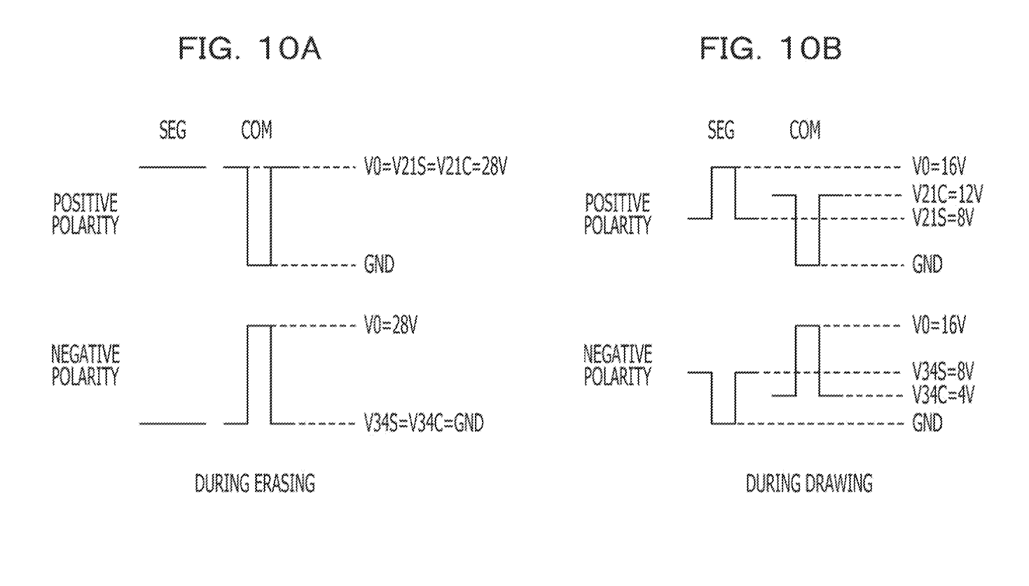

FIGS. 10A and 10B illustrate exemplary driver output voltages. FIG. 10A illustrates a driver output signal during erasing. FIG. 10B illustrates a driver output signal during drawing. Reference sign GND denotes a ground potential (0 V). Since the output voltages of the segment driver 16 and the common driver 17 during erasing differ from output voltages during drawing, the voltage supply circuit of the multi-voltage generating circuit 13 supplies different voltages to the driver 16 or 17.

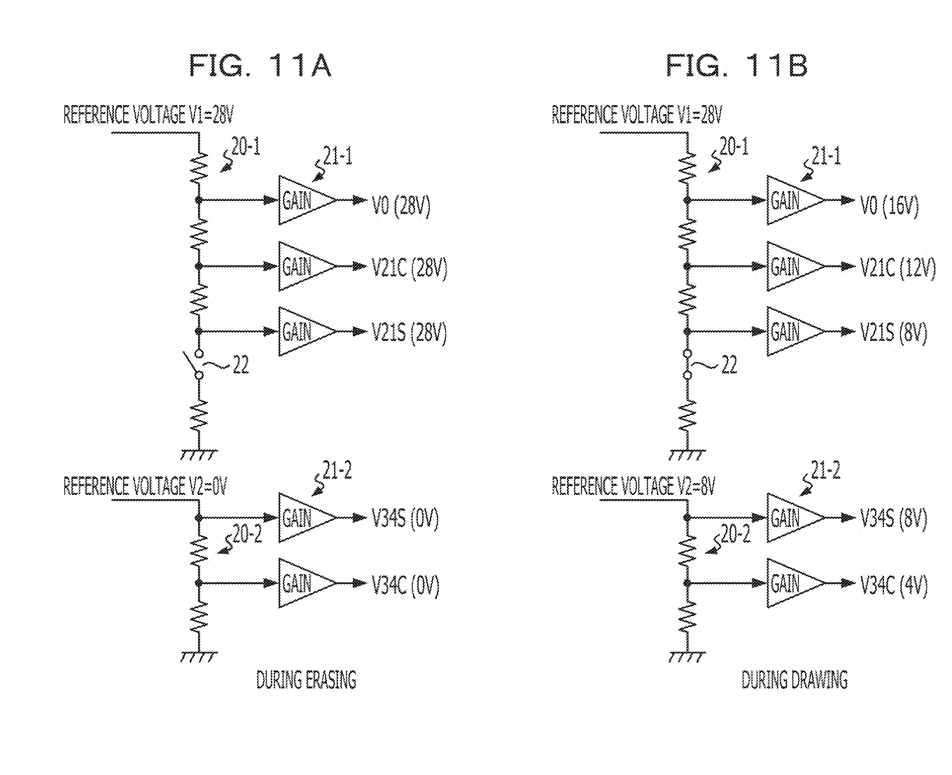

FIGS. 11A and 11B illustrate exemplary voltage switchings. Voltages supplied to the segment driver 16 and the common driver 17 of the voltage supply circuits of the multi-voltage generating circuit 13 may be switched. In FIGS. 11A and 11B, elements that are substantially the same as those illustrated in FIGS. 7A and 7B are given the same reference signs, and descriptions thereof will be omitted or reduced. FIG. 11A illustrates an erasing state in which the switch 22 is off. FIG. 11B illustrates a drawing state when the switch 22 is on. The voltage supply circuits having a voltage follower configuration including the amplifier circuits illustrated in FIGS. 11A and 11B supply different voltages to the driver 16 or 17 by switching the reference voltage between V1 and V2 at erasing and at drawing.

When the voltage supplied to the driver 16 or 17 is not switched normally, the relation of V0≧V21≧V34≧V5≧0 V may not be satisfied in the driver 16 or 17. This may damage the driver 16 or 17 or may increase the power consumption of the display apparatus 1.

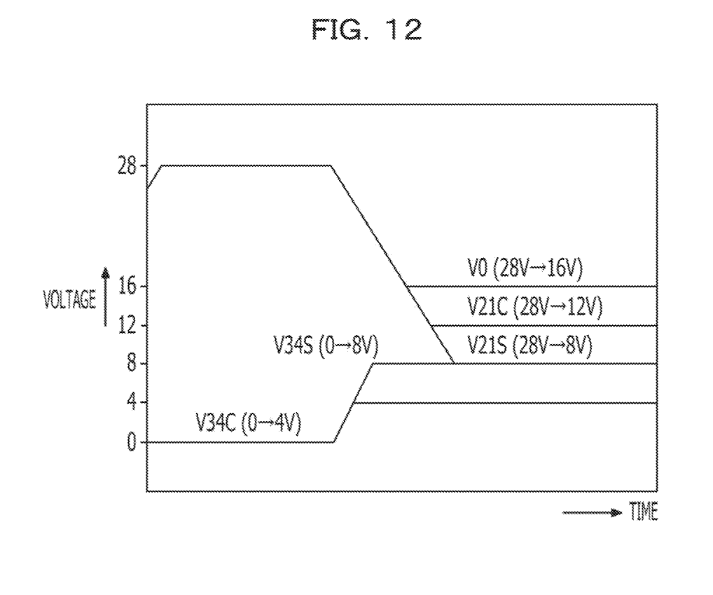

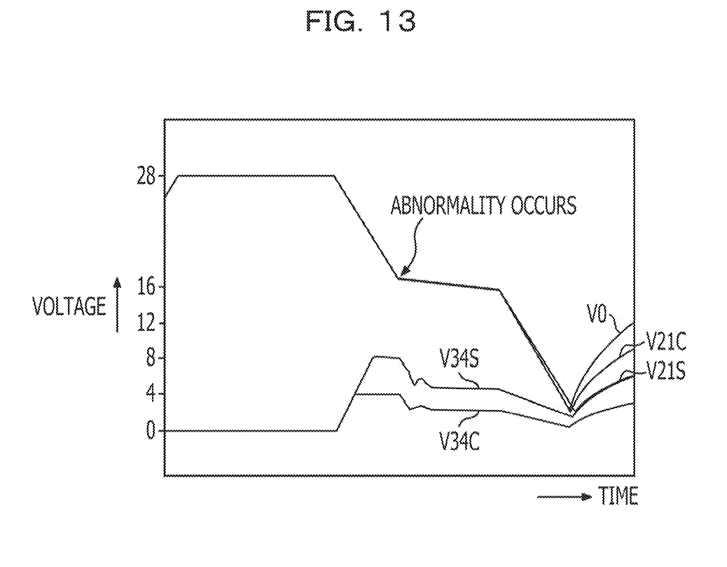

FIG. 12 illustrates an exemplary voltage. The voltage illustrated in FIG. 12 may be a voltage when the voltage is switched normally between erasing and drawing in the voltage supply circuit. FIG. 13 illustrates an exemplary voltage. The voltage illustrated in FIG. 13 illustrates a voltage when the voltage is not normally switched between erasing and drawing in the voltage supply circuit. The vertical axes illustrated in FIGS. 12 and 13 indicate the output voltage (V) of the voltage supply circuit. The horizontal axes indicate time in any unit. In FIG. 12, the voltage V34C switches from 0 V to 4 V, the voltage V34S switches from 0 V to 8 V, the voltage V0 switches from 28 V to 16 V, the voltage V21C switches from 28 V to 12 V, and the voltage V21S switches from 28 V to 8 V. In FIG. 12, the driver 16 or 17 has the relation of V0≧V21≧V34 V5≧0 V. When the voltage is not switched normally between at erasing and at drawing, the driver 16 or 17 may not have the relation of V0≧V21≧V34≧V5≧0 V, as illustrated in FIG. 13, therefore, an image may not be displayed normally.

For example, if a voltage switching speed when the highest-potential voltage V0 is switched to another voltage differs from a voltage switching speed when the voltage V21 lower than the voltage V0 is switched to another voltage, the voltage may be switched normally. When the voltage switching speed is set so as to satisfy the relation of (the switching speed of V0)<the switching speed of V21C) and (the switching speed of V0)<(the switching speed of V21S), the segment driver 16 may have the relation of V0≧V21S or the common driver 17 may have the relation of V0≧V21C. The low potential voltages V34S and V34C may be at 0 V during erasing and may be 8 V and 5 V during drawing, respectively. The switching of the voltage from erasing to drawing is in a voltage increasing direction.

For example, a voltage switching speed or a voltage switching timing when a voltage is switched to another voltage may be set by at least one of the following methods (1) to (4).

(1) A current sink speed of an operational amplifier, which outputs the voltage V0, in the voltage supply circuit is set lower than the current sink speed of an operational amplifier which outputs the voltage V21S or V21C. The current sink speed may also be referred to as a through rate or a sink through rate.

(2) A current limiter circuit, which outputs the voltage V0, is coupled to the operational amplifier, in the voltage supply circuit, to limit a current during switching the voltage.

(3) A booster circuit is coupled to an operational amplifier, which outputs the voltage V21S or V21C, in the voltage supply circuit and the sink current or the current sink capacity of the operational amplifier is set higher than that of the operational amplifier that outputs the voltage V0.

(4) A switch, which switches the higher voltage V0, in the voltage supply circuit is switched earlier than a switch which switches the lower voltage V21S or V21C.

Since the voltage switching speed or switching timing of the higher-potential voltage V0 differs from the voltage switching speed or switching timing of the lower voltage V21, the voltage may be switched normally. This may reduce damages of the drivers 16 and 17 and the power consumption of the display apparatus 1.

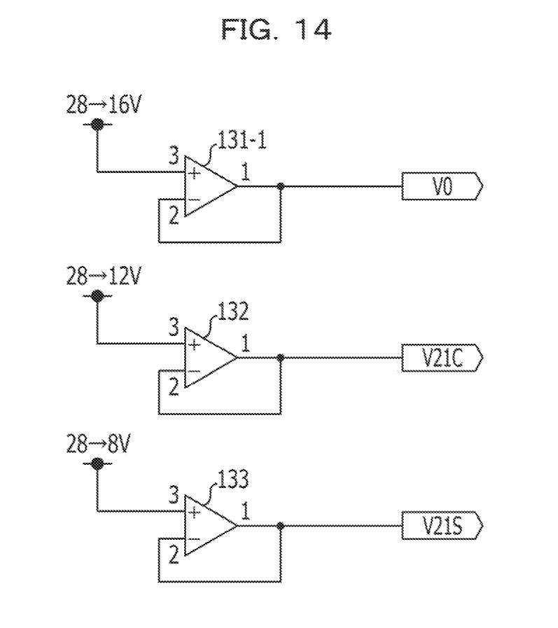

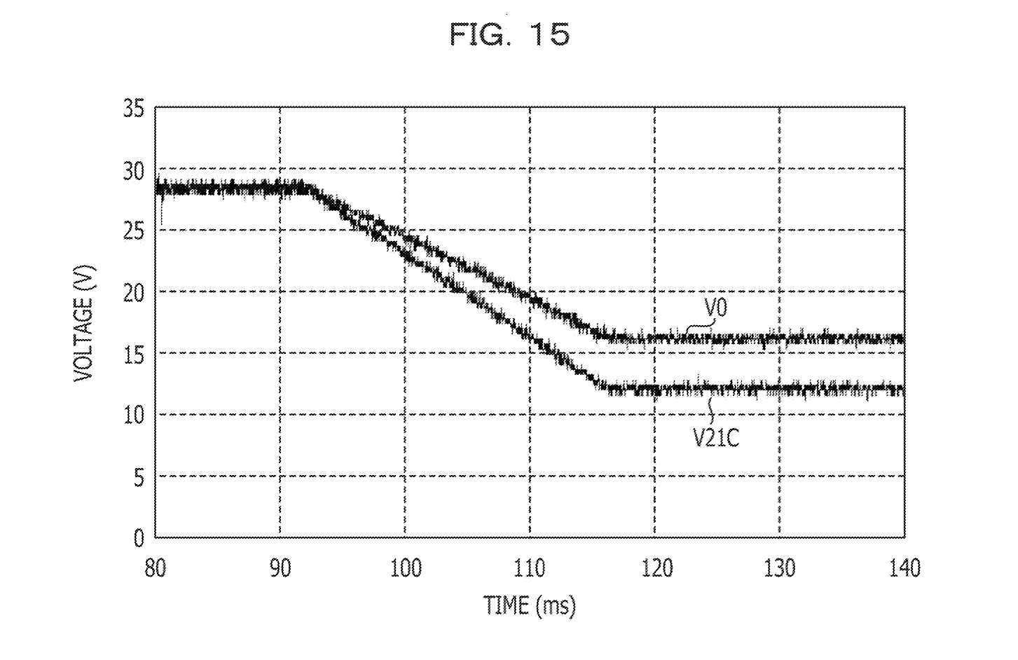

FIG. 14 illustrates an exemplary voltage supply circuit. FIG. 15 illustrates an exemplary output voltage. The output voltage illustrated in FIG. 15 may be an output voltage when the voltage supply circuit illustrated in FIG. 14 switches between the voltages. The vertical axis illustrated in FIG. 15 indicates the output voltage (V) of the voltage supply circuit, and the horizontal axis illustrated in FIG. 15 indicates time (ms).

As illustrated in FIG. 14, the voltage supply circuit includes operational amplifiers 131-1, 132, and 133. The operational amplifier 131-1 is supplied with the voltage V0 from the topmost amplifier circuit of the amplifier circuit group 21-1 illustrated in FIG. 11A or 11B. The operational amplifier 132 is supplied with the voltage V21C from the second amplifier circuit from the top of the amplifier circuit group 21-1 illustrated in FIG. 11A or 11B. The operational amplifier 133 is supplied with the voltage V21S from the lowermost amplifier circuit of the amplifier circuit group 21-1 illustrated in FIG. 11A or 11B. The sink through rate of the operational amplifier 131-1 that outputs the voltage V0 is lower than the sink through rate of the operational amplifier 132 or 133 that outputs the voltage V21S or V21C. For example, when the sink through rate of the operational amplifier 132 or 133 that outputs the voltage V21C or V21C is 2 V/ms, the sink through rate of the operational amplifier 131-1 that outputs the voltage V0 may be about 1 V/ms. The current discharge rate or the source through rate may be substantially the same as that of the operational amplifier 131-1, 132, or 133 that outputs the voltage V0, V21S, or V21C.

At switching from erasing to drawing, in the segment driver 16, the voltage V0=28 V may be switched to 16 V at 1 V/ms, and the voltage V21S=28 V may be switched to 8 V at 2 V/ms. At the start of voltage switching, the voltage V0 and the voltage V21S may be substantially the same, at 28V. Therefore, the voltage V21S may be switched to the drawing voltage at a high speed, so that the relation of V0≧V21S may be satisfied. As illustrated in FIG. 15, the voltage may be switched, with the voltage V0 being held high. Also in the common driver 17, the voltage V0=28 V may be switched to 16 V at 1 V/ms, and the voltage V21C=28 V may be switched to 12 V at 2 V/ms, as in the segment driver 16. Therefore, the relation of V0≧V21C may be satisfied.

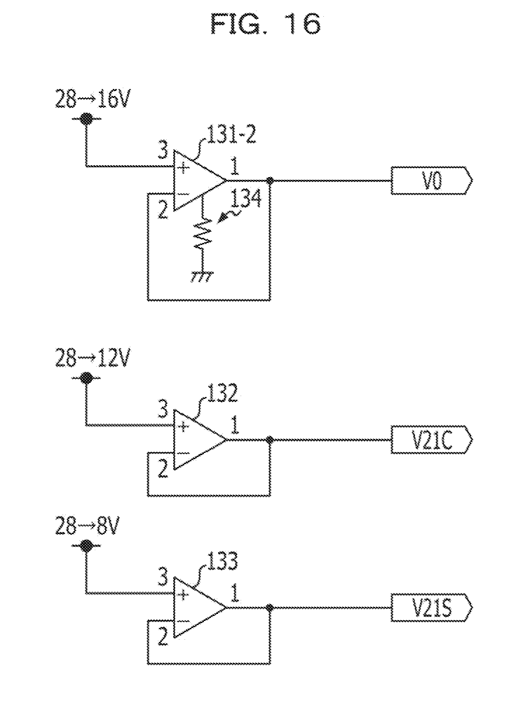

FIG. 16 illustrates an exemplary voltage supply circuit. In FIG. 16, substantially the same elements as those in FIG. 14 are given the same reference signs, and descriptions thereof will be omitted or reduced.

The voltage supply circuit illustrated in FIG. 16 may include, instead of the operational amplifier 131-1, an operational amplifier 131-2 in which a resistor 134 is coupled to a negative power supply terminal. Since the resistor 134 is coupled to the negative power supply terminal of the operational amplifier 131-2 to which the voltage V0 is supplied, the sink current of the operational amplifier 131-2 may be reduced. For example, when the sink current of the operational amplifier 132 or 133 to which the voltage V21C or V215 is supplied is 1 mA, the sink current of the operational amplifier 131-2 may be less than 1 mA by setting the resistance of the resistor 134 to 1 kiloOhm (kΩ) to 2 kΩ. Thus, the sink current of the operational amplifier 131-2 to which the voltage V0 is supplied may become lower than the sink current of the operational amplifier 132 or 133 to which the voltage V21C or V215 is supplied. The power supply circuit illustrated in FIG. 16 may offer substantially the same or similar advantages as those of the voltage supply circuit illustrated in FIG. 14.

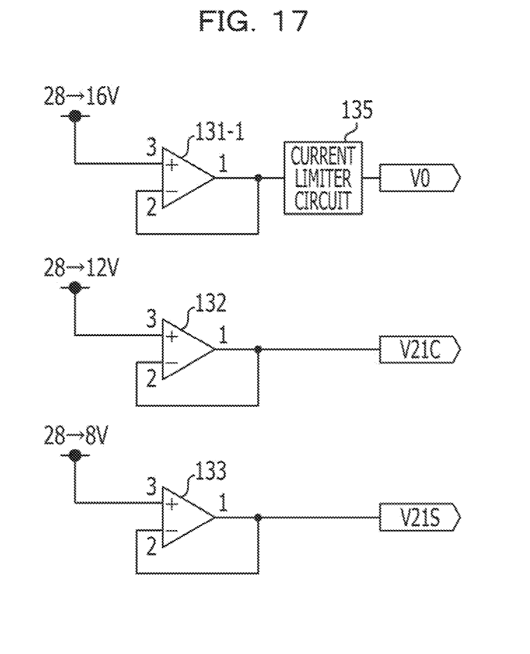

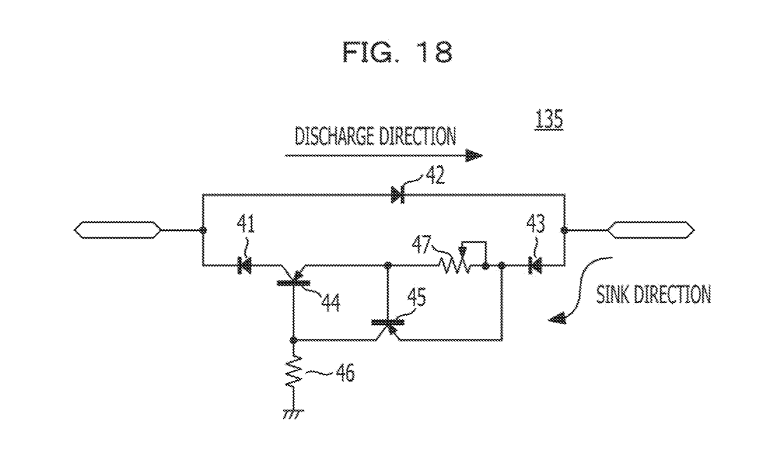

FIG. 17 illustrates an exemplary voltage supply circuit. FIG. 18 illustrates an exemplary current limiter circuit. The current limiter circuit illustrated in FIG. 18 may be the power-supply limiter circuit illustrated in FIG. 17. In FIG. 17, substantially the same elements as those in FIG. 14 are given the same reference signs, and descriptions thereof will be omitted or reduced.

The voltage supply circuit illustrated in FIG. 17 includes a current limiter circuit 135 coupled to the output of the operational amplifier 131-1. As illustrated in FIG. 18, the current limiter circuit 135 may include, for example, diodes 41, 42, and 43, transistors 44 and 45, and resistors 46 and 47. The current limiter circuit 135 illustrated in FIG. 18 sets a limit current based on the resistance of the resistor 47 and sets the sink current of the operational amplifier 131-1 to less than the sink current of the operational amplifier 132 or 133 based on the resistance. The power supply circuit illustrated in FIG. 17 may offer substantially the same or similar advantages as those of the voltage supply circuit illustrated in FIG. 14.

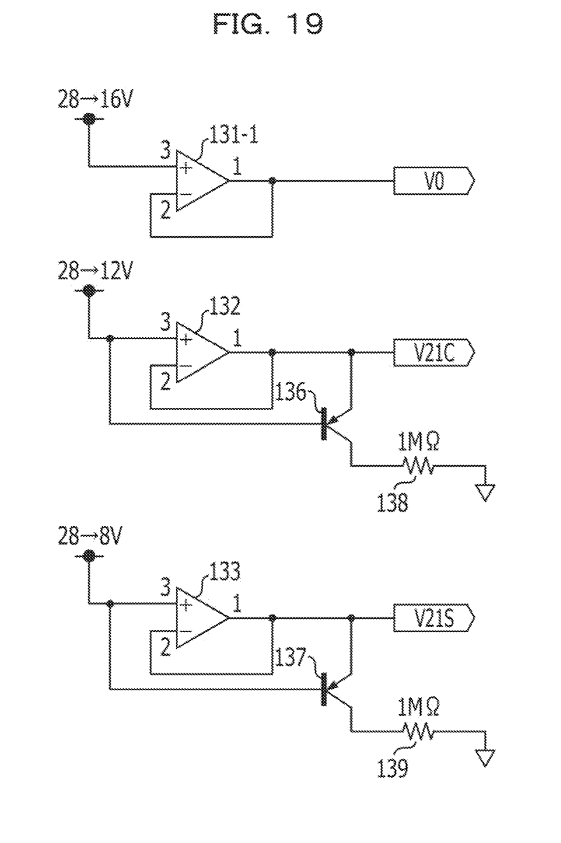

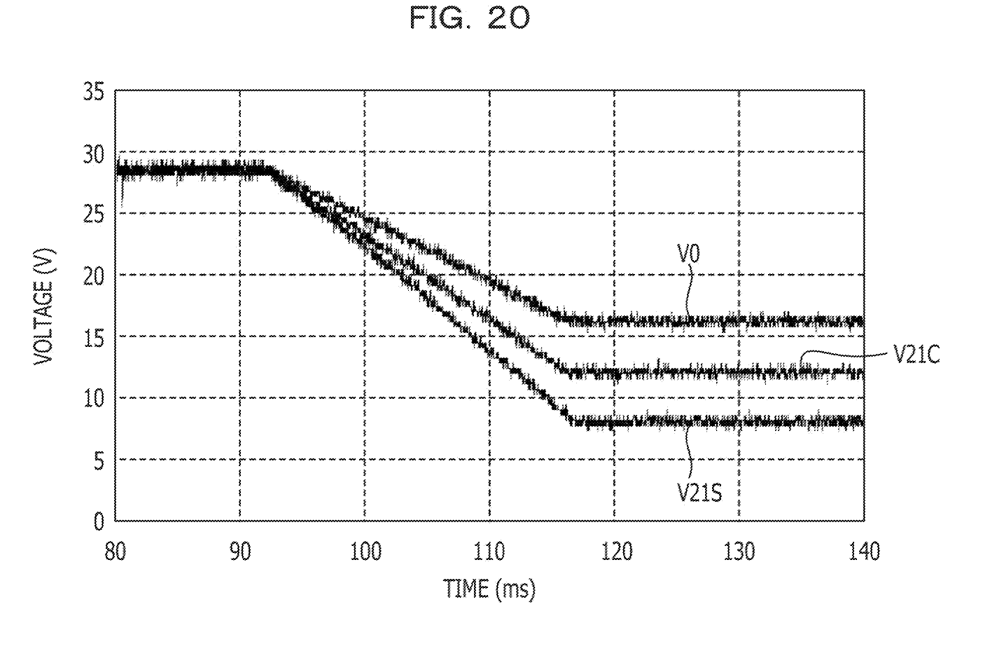

FIG. 19 illustrates an exemplary voltage supply circuit. FIG. 20 illustrates an exemplary output voltage. The output voltage illustrated in FIG. 20 may be an output voltage when the voltage supply circuit illustrated in FIG. 19 switches between the voltages. In FIG. 19, substantially the same elements as those in FIG. 14 are given the same reference signs, and descriptions thereof will be omitted or reduced. The vertical axis illustrated in FIG. 20 indicates the output voltage (V) of the voltage supply circuit. The horizontal axis illustrated ion FIG. 20 indicates time in milliseconds (ms).

The voltage supply circuit illustrated in FIG. 19 includes a booster circuit coupled to the output of the operational amplifier 132 and including a transistor 136 and a resistor 138, and a booster circuit coupled to the output of the operational amplifier 133 and including a transistor 137 and a resistor 139. In the booster circuit coupled to the operational amplifier 132 or 133, for example, the resistance of the resistor 138 or 139 is set to 1 MegaOhm (MΩ), so that the sink current, for example, the current sink capacity, of the operational amplifier 132 or 133 becomes higher than the sink current, for example, the current sink capacity, of the operational amplifier 131-1. Since the sink current of the operational amplifier 132 or 133 becomes higher, the voltage change of the operational amplifier 132 or 133 becomes faster than the voltage change of the operational amplifier 131-1, as illustrated in FIG. 20, so that the relation of V0≧V21S and V0≧V21C may be satisfied. The power supply circuit illustrated in FIG. 19 may offer substantially the same or similar advantages as those of the voltage supply circuit shown in FIG. 14.

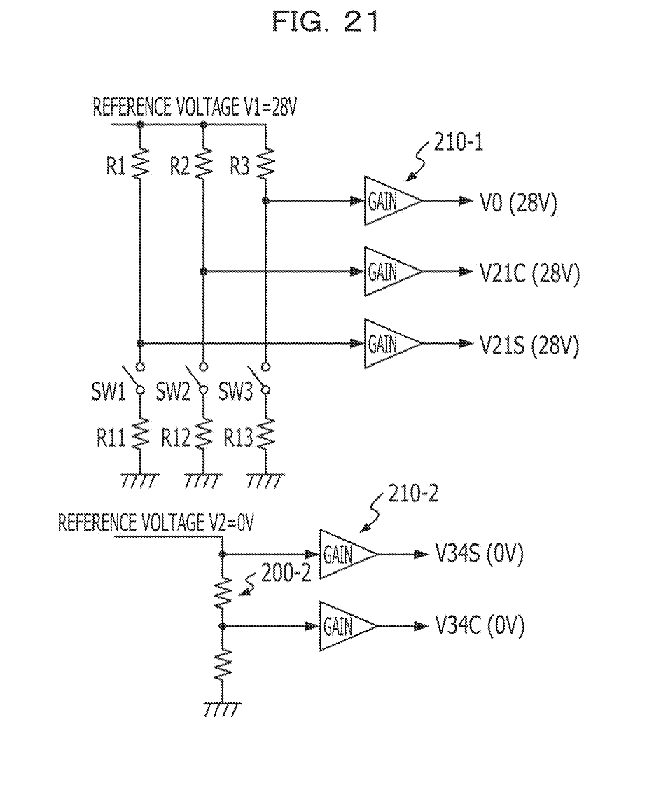

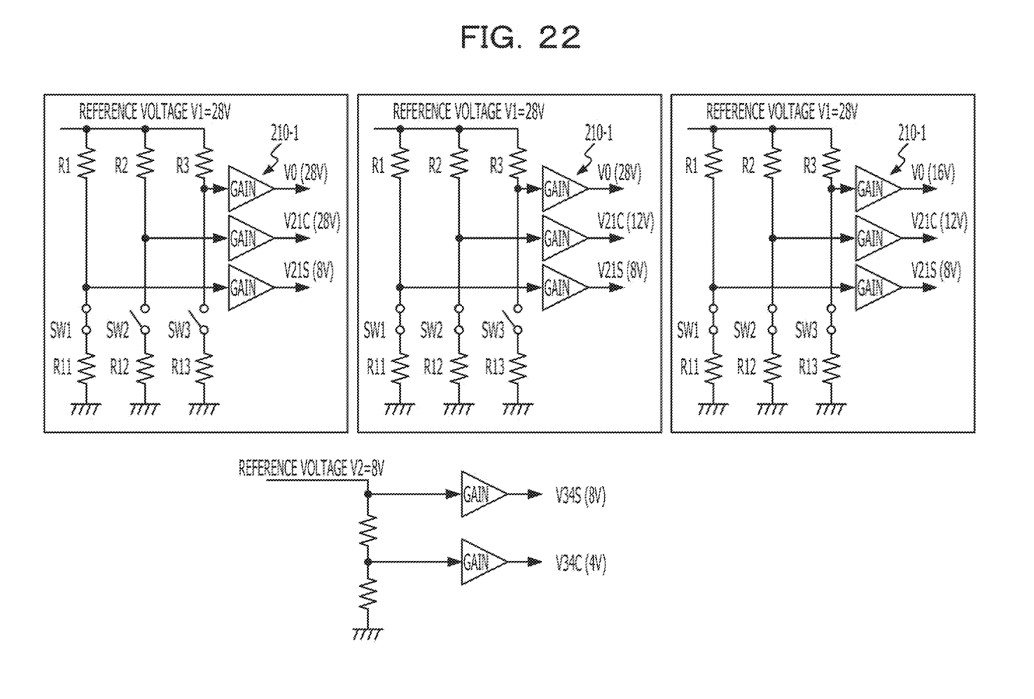

FIG. 21 illustrates an exemplary power supply circuit. The voltage supply circuit illustrated in FIG. 21 may perform an erasing operation. FIG. 22 illustrates an exemplary voltage supply circuit. The power supply circuit illustrated in FIG. 22 may perform a drawing operation.

The voltage supply circuit is supplied with the reference voltage V1 and the reference voltage V2. The reference voltage V1 is supplied to resistors R1, R2, and R3, switches SW1, SW2, and SW3, resistors R11, R12, and R12, and the amplifier circuit group 210-1 including three amplifier circuits. The reference voltage V2 is supplied to a resistor group 200-2 including two resistors and to an amplifier circuit group 210-2 including two amplifier circuits. Since the reference voltage V1 is divided by the resistors R1 and R11, the resistors R2 and R12, or the resistors R3 and R13 depending on the switches SW1, SW2, and SW3, this may correspond to substantially a case where a plurality of power supplies are provided at the reference voltage V1 side.

As illustrated in FIG. 21, the switches SW1, SW2, and SW3 are turned off at erasing. At drawing, as illustrated in FIG. 22, when the switches SW1, SW2, and SW3 are in the off state, the switch SW1 is turned on, the switch SW2 is next turned on, and the switch SW3 is next turned on, so that the voltages V0, V21C, and 21S may be switched at different times.

When the voltage is switched between erasing and drawing, the relation of V0≧V21S and V0≧V21C may be satisfied. This allows the switching of voltages to be performed normally, which may reduce damages on the drivers 16 and 17 and power consumption of the display apparatus 1.

All examples and conditional language recited herein are intended for pedagogical objects to aid the reader in understanding the invention and the concepts contributed by the inventor to furthering the art, and are to be construed as being without limitation to such specifically recited examples and conditions. Although the embodiment(s) of the present inventions have been described in detail, it should be understood that the various changes, substitutions, and alterations could be made hereto without departing from the spirit and scope of the invention.

1. A voltage supply circuit comprising,
a switching circuit to switch among a plurality of driving voltages including a first driving voltage and a second driving voltage lower than the first driving voltage based on an operation mode of a display apparatus and control at least one of a switching speed and a switching timing so that one of a first switching speed and a first switching timing to the first driving voltage becomes faster than a corresponding one of a second switching speed and a second switching timing to the second driving voltage.

2. The voltage supply circuit according to claim 1, wherein the switching circuit includes:
a first amplifier circuit to output the first driving voltage; and
a second amplifier circuit to output the second driving voltage,
a sink through rate of the first amplifier circuit is lower than a sink through rate of the second amplifier circuit.

3. The voltage supply circuit according to claim 1, wherein the switching circuit includes:
a first amplifier circuit to output the first driving voltage;
a second amplifier circuit to output the second driving voltage; and
a current control circuit coupled to the first amplifier circuit to control a current flowing at a switching of at least one of the first driving voltage and the second driving voltage.

4. The voltage supply circuit according to claim 1, wherein the switching circuit includes:
a first amplifier circuit to output the first driving voltage;
a second amplifier circuit to output the second driving voltage; and
a booster circuit coupled to the second amplifier circuit to increase a sink current of the second amplifier circuit relative to a sink current of the first amplifier circuit.

5. The voltage supply circuit according to claim 1, wherein the switching circuit includes:
a first switch to switch the first driving voltage; and
a second switch to switch the second driving voltage, the second switch is switched after the first switch is switched.

6. A display apparatus comprising:
a display element circuit;
a driving circuit to drive the display element circuit;
a voltage generating circuit to switch among a plurality of driving voltages between erasing and drawing of an image and to supply at least one of the plurality of driving voltages to the driving circuit; and
a voltage supply circuit to control at least one of a switching speed and a switching timing so that one of a switching speed and a switching timing of the first driving voltage becomes faster than a corresponding one of a switching speed and a switching timing of a second driving voltage, the second driving voltage being lower than the first driving voltage.

7. The display apparatus according to claim 6, wherein the voltage supply circuit includes;
a first amplifier circuit to output the first driving voltage; and
a second amplifier circuit to output the second driving voltage,
a sink through rate of the first amplifier circuit is lower than a sink through rate of the second amplifier circuit.

8. The display apparatus according to claim 6, wherein the voltage supply circuit includes:
a first amplifier circuit to output the first driving voltage;
a second amplifier circuit to output the second driving voltage; and
a current limiter circuit coupled to the first amplifier circuit to control a current flowing at a switching of at least one of the first driving voltage and the second driving voltage.

9. The display apparatus according to claim 6, wherein the voltage supply circuit includes:
a first amplifier circuit to output the first driving voltage;
a second amplifier circuit to output the second driving voltage; and
a booster circuit coupled to the second amplifier circuit to increase a sink current of the second amplifier circuit relative to a sink current of the first amplifier circuit.

10. The display apparatus according to claim 6, wherein the voltage supply circuit includes:
a first switch to switch the first driving voltage; and
a second switch to switch the second driving voltage, the second switch is switched after the first switch is switched.

11. The display apparatus according to claim 6, wherein the display element circuit includes a cholesteric liquid crystal.
